(19) United States
(12) Patent Application Publication
(10) Pub. No.: US 2012/0183679 A1
(43) Pub. Date: Jul. 19, 2012

(54) METHOD FOR MAKING AN ELECTROCHEMICAL SENSOR STRIP

(76) Inventor: Jian-Hua CHEN, Hsinchu City (TW)

(21) Appl. No.: 13/352,018

(22) Filed: Jan. 17, 2012

(30) Foreign Application Priority Data
Jan. 18, 2011 (TW) 100101799

(51) Int. Cl. H05K 3/28; C25D 5/02

(52) U.S. Cl. 427/96.2; 205/125

(57) ABSTRACT

A method for making an electrochemical sensor strip is provided which comprises the following steps: forming a circuit layer on a first substrate; forming a protective film on the first substrate such that the protective film covers a first portion of the circuit layer on the first substrate; forming an electrode layer on a second portion of the circuit layer; and coating a reagent on at least a portion of the electrode layer or the first substrate and disposing a second substrate on the first substrate.

### BACKGROUND OF THE INVENTION

(a) Field of the Invention

The invention relates to a method for making an electrochemical sensor strip, particularly to a method for making an electrochemical sensor strip with partial electrodes.

(b) Description of the Related Art

Electrochemical sensor strips have been extensively applied in various fluid measurement. The basic principle is that a reagent reacts with a test object in a test fluid to have a chemical reaction and then an electric output signal generated in the test fluid is measured where the characteristic of the electric output signal is related to the test object in the test fluid. For example, when the test fluid is human blood and the test object is blood sugar, glucose oxidase and other composite compounds can be used as the reagent.

FIG. 1 shows a schematic diagram illustrating the exterior of an electrochemical sensor strip according to the prior art. FIG. 2 shows a schematic diagram illustrating the parts breakdown of the electrochemical sensor strip of FIG. 1. As shown in FIGS. 1 and 2, the electrochemical sensor strip 100 is a blood sugar test strip and comprises an electrode substrate 110, a flow channel plate 120 and a top plate 130. The electrode substrate 110 comprises a circuit layout 112 and a substrate 111 and generally the electrode substrate 110 is formed by printing the circuit layout 112 on the substrate 111. The flow channel plate 120 has a notch 122 thereon and the notch 122 penetrates the upper and the lower surfaces of the flow channel plate 120. In order to have the blood flow smoothly, an opening 135 on the top plate 130 is disposed at a position corresponding to the notch 122 of the flow channel plate 120.

When the electrochemical sensor strip 100 is fabricated, the electrode substrate 110, the flow channel plate 120 and the top plate 130 are to be laminated. The flow channel plate 120 is placed between the electrode substrate 110 and the top plate 130 and the electrode substrate 110, the flow channel plate 120 and the top plate 130 together define a flow channel 150. The position of the flow channel 150 corresponds to that of the notch 122 of the flow channel plate 120 and the flow channel 150 has an inlet 125 and an outlet 135. During operation, blood is dropped on the inlet 125 by a user and the blood flows into the flow channel 150 from the inlet 125. The blood will flow in the flow channel 150 because of capillarity and then gas in the flow channel 150 is expelled from the outlet 135.

However, the electrochemical sensor strip 100 according to the prior art still requires further improvement.

### BRIEF SUMMARY OF THE INVENTION

One object of one embodiment of the invention is to provide a method for making an electrochemical sensor strip. One object of one embodiment of the invention is to provide a method for making an electrochemical sensor strip with partial electrodes.

One embodiment of the invention provides a method for making an electrochemical sensor strip. The method comprises the following steps. A circuit layer is formed on a first substrate. A protective film is formed on the first substrate such that the protective film covers a first portion of the circuit layer. An electrode layer is formed on a second portion of the circuit layer and the material of the electrode layer is different from that of the circuit layer. A reagent is coated on at least a portion of the electrode layer and a second substrate is disposed on the first substrate. The first substrate and the second substrate define a flow channel and the flow channel is at a position corresponding to the at least a portion of the electrode layer coated with the reagent.

In one embodiment, the step of forming a protective film on the first substrate comprises using a screen printing technique or an inkjet printing technique to form the protective film on the first substrate.

In one embodiment, the step of forming an electrode layer on a second portion of the circuit layer comprises using a deposition technique to form the electrode layer on the second portion of the circuit layer.

In one embodiment, the deposition technique is an electroplating technique and the step of using a deposition technique to form the electrode layer on the second portion of the circuit layer comprises the following steps. A metal clamping tool is used to clamp the first substrate and the metal clamping tool is in contact with a portion of the circuit layer without being covered by the protective film. The second portion of the first substrate formed with the circuit layer and the protective film is placed in an electroplating solution. A power source is applied to the circuit layer through the metal clamping tool.

In one embodiment, the deposition technique is an electroless plating technique.

According to one embodiment of the invention, the electrode layer and the circuit layer are formed separately. Therefore, partly-finished products of electrochemical sensor strips can be massively produced and then an electrochemical sensor strip having a specific measurement function can be made according to product design requirements such that the production cost can be reduced. Furthermore, since the material of the electrode layer is different from that of the circuit layer, the material of the electrode layer can be selected suitable to the reagent in use and the more accurate measurement can be obtained. In one embodiment, the electrode layer is made of noble metal and the circuit layer is made of conductive material other than noble metal. Thus, the amount of noble metal to be used can be reduced and the production cost can be reduced as well.

Other objects and advantages of the invention can be better understood from the technical characteristics disclosed by the invention. In order to clarify the above mentioned and other objects and advantages of the invention, examples accompanying with figures are provided and described in details in the following.

### BRIEF DESCRIPTION OF THE DRAWINGS

FIG. 1 shows a schematic diagram illustrating the exterior of an electrochemical sensor strip according to the prior art.

FIG. 2 shows a schematic diagram illustrating the parts breakdown of the electrochemical sensor strip of FIG. 1.

FIG. 3 shows a flow chart of a method for making an electrochemical sensor strip according to one embodiment of the invention.

FIGS. 4A-4F show schematic diagrams illustrating the steps of the method for making an electrochemical sensor strip according to one embodiment of the invention.

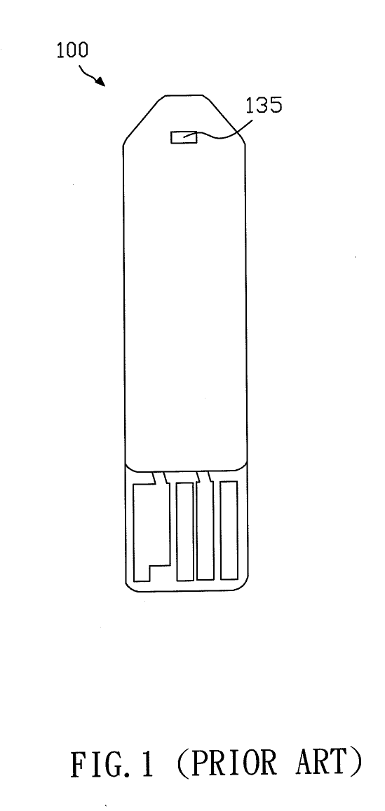

### DETAILED DESCRIPTION OF THE INVENTION

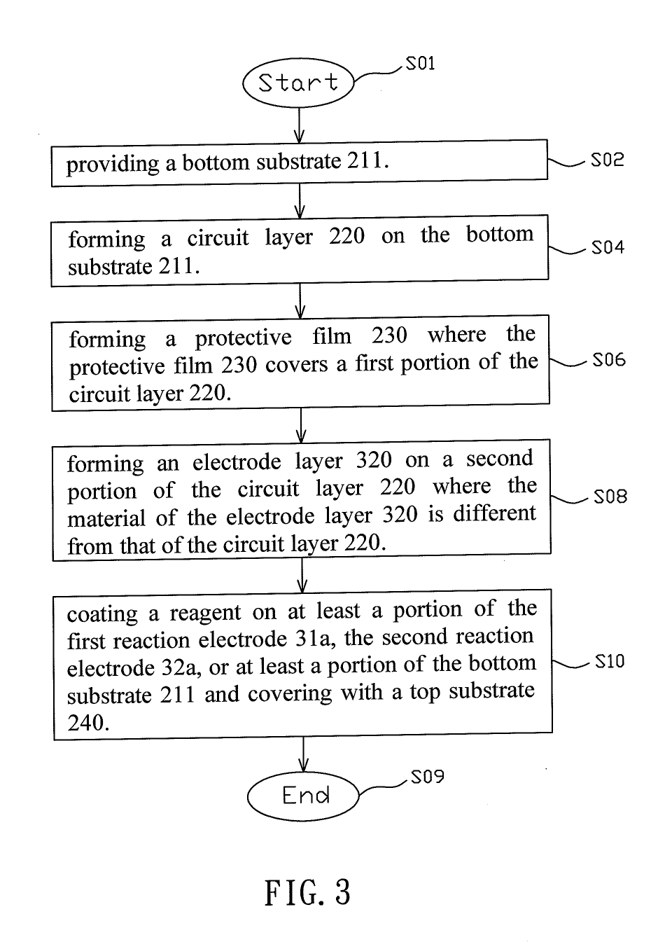

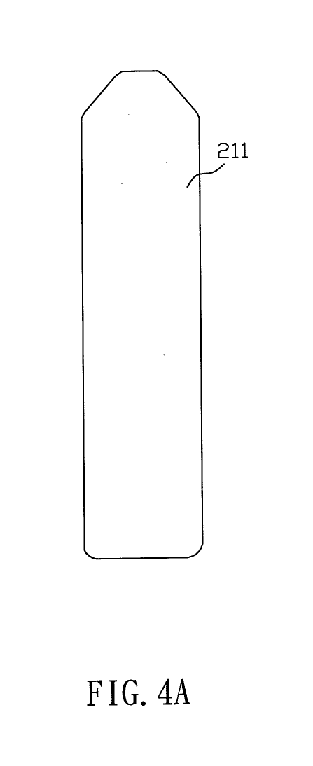

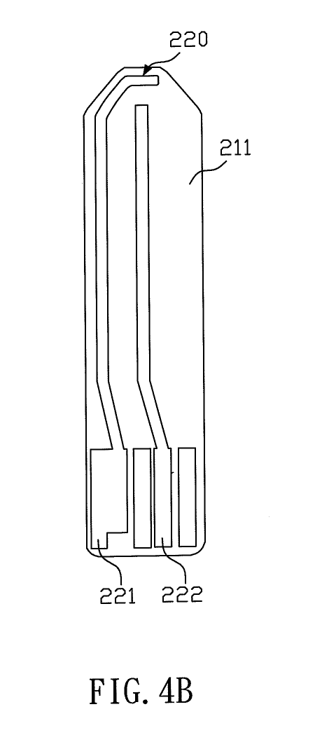

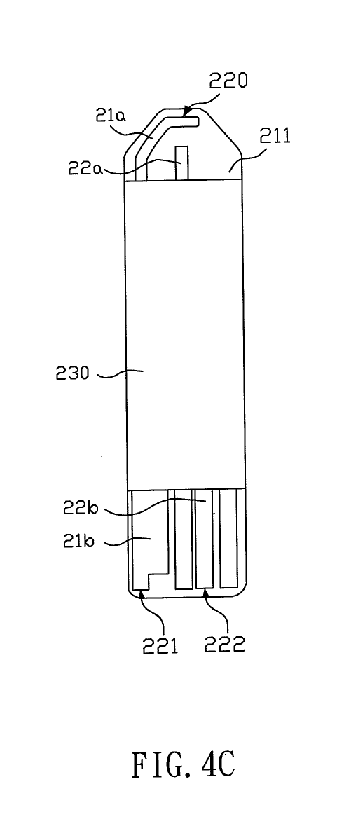

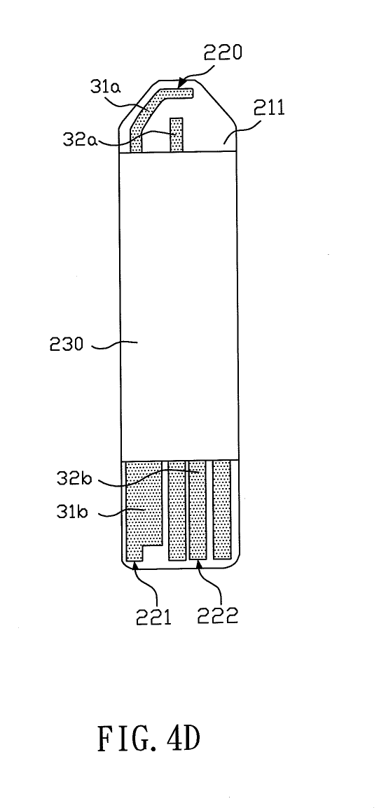

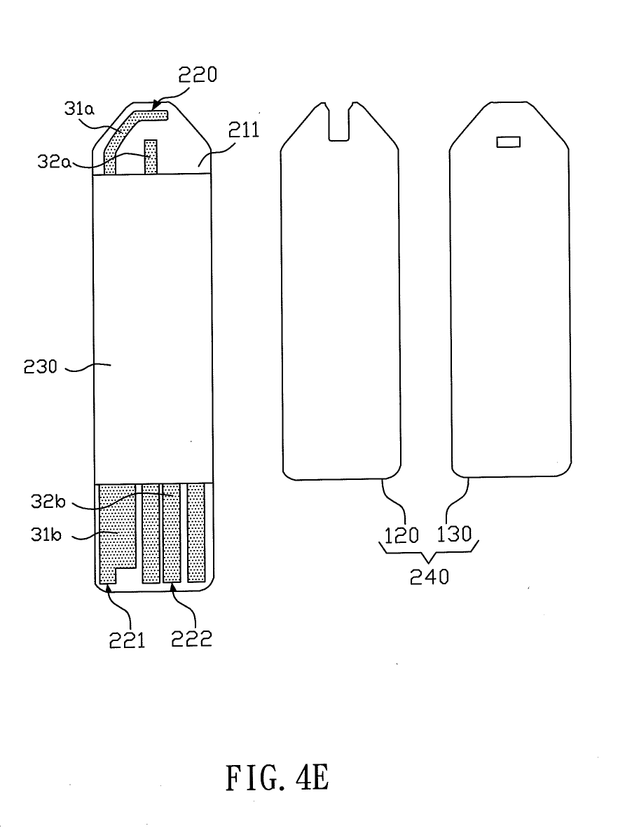

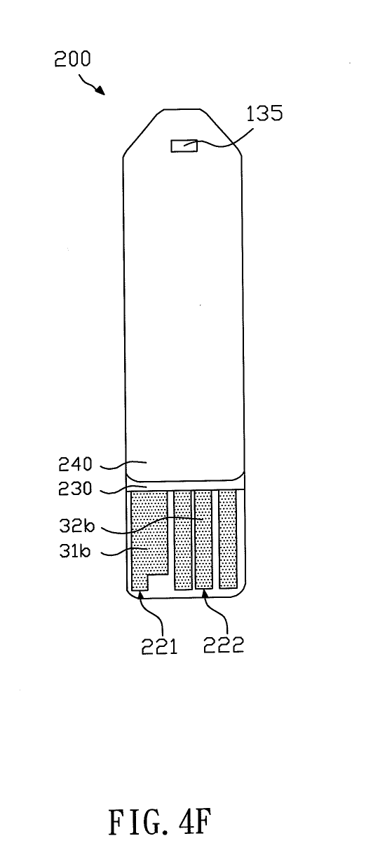

FIG. 3 shows a flow chart of a method for making an electrochemical sensor strip according to one embodiment of the invention. FIGS. 4A-4F show schematic diagrams illustrating the steps of the method for making an electrochemical sensor strip according to one embodiment of the invention. As shown in FIG. 3 and FIGS. 4A-4F, the method for making an electrochemical sensor strip according to one embodiment of the invention comprises the following steps.

As shown in FIG. 4A, step S02: providing a bottom substrate 211.

As shown in FIG. 4B, step S04: forming a circuit layer 220 on the bottom substrate 211. In one embodiment, the circuit layer 220 comprises a first circuit 221 and a second circuit 222. The invention does not limit the method of forming the circuit layer 220. As long as the circuit layer 220 is electrically conductive, the material of the circuit layer 220 is not limited. Preferably, the circuit layer 220 can be formed by screen printing and the material of the circuit layer 220 can be graphite, silver paste or aluminum paste, etc. Besides, in one embodiment, the circuit layer 220 can be formed by depositing a film by vapor deposition, electroplating, sputtering, and electroless plating, etc. and patterning the film by etching, scribing or other separation techniques and thus the material of the circuit layer 220 can be metal such as aluminum, copper, titanium, nickel, chromium, tungsten, iron, etc. and metal alloy thereof; or conductive films such as oxide conductive films.

As shown in FIG. 4C, step S06: forming a protective film 230 where the protective film 230 covers a first portion of the circuit layer 220. In this embodiment, the protective film 230 covers the central portions of the first circuit 221 and the second circuit 222. A first reaction portion 21a and a first measurement portion 21b on the two ends of the first circuit 221 are exposed; and a second reaction portion 22a and a second measurement portion 22b on the two ends of the second circuit 222 are exposed. The invention does not limit the method of forming the protective film 230. As long as the protective film 230 is made of electrical insulation material, the material of the protective film 230 is not limited. Preferably, the protective film 230 is formed by screen printing.

As shown in FIG. 4D, step S08: forming an electrode layer 320 on a second portion of the circuit layer 220 where the material of the electrode layer 320 is different from that of the circuit layer 220. In this embodiment, the electrode layer 320 is formed by a plating technique on the portion of the circuit layer 220 unprotected by the protective film 230, that is, the portion of the circuit layer 220 which is not covered by the protective film 230. Specifically, the electrode layer 320 comprises a first reaction electrode 31a and a second reaction electrode 32a. In one embodiment, the electrode layer 320 further comprises a first measurement electrode 31b and a second measurement electrode 32b. The first reaction electrode 31a, the first measurement electrode 31b, the second reaction electrode 32a, and second measurement electrode 32b are formed on the first reaction portion 21a, the first measurement portion 21b, the second reaction portion 22a, and the second measurement portion 22b, respectively. The invention does not limit the method of forming the electrode layer 320. The material of the electrode layer 320 is not limited and can be selected according to the product design. In one embodiment, the material of the electrode layer 320 can be noble metal (precious metal) such as Au, Pt, Ag, Ir, Os, Pd, Rh, Ru and metal alloy thereof; or conductive films such as oxide conductive films. In one embodiment, the material of the electrode layer 320 can be graphite and formed by screen printing.

In one embodiment, electroplating is used to form an electrode layer 320 on a second portion of the circuit layer 220. Specifically, a metal clamping tool is used to clamp the bottom substrate 211 and the metal clamping tool is in contact with the uncovered portion of the circuit layer 220 wherein the uncovered portion is not covered by the protective film 230 (step S32). At least a portion of the bottom substrate 211 formed with the circuit layer 220 and the protective film 230 is placed in an electroplating solution (step S34). A power source is applied to the circuit layer 220 through the metal clamping tool and the electrode layer 320 can be formed on the uncovered portion of the circuit layer 220 (step S36). The covered portion of the circuit layer 220 by the protective film 230 will not be coated because it is not in contact with the electroplating solution. Besides, in one embodiment of step S34, only the front end portion of the bottom substrate 211 is dipped into the electroplating solution to have the first reaction portion 21a and the second reaction portion 22a be in contact with the electroplating solution such that in step S36 the first reaction electrode 31a and the second reaction electrode 32a can be formed. In one embodiment, the whole bottom substrate 211 is dipped into the electroplating solution and the above electrodes are formed at the same time.

In one embodiment, electroless plating is used to form an electrode layer 320 on a second portion of the circuit layer 220. Electroless plating is a surface treatment technique by utilizing autocatalytic effect to deposit alloy on the surface of an object. Specifically, the bottom substrate 211 formed with the circuit layer 220 is placed in the chemical solution but the portion of the circuit layer 220 covered by the protective film 230 is not in contact with the chemical solution. Thus, the electrode layer is formed only on the uncovered portion of the circuit layer 220 but not the covered portion. As described previously, in one embodiment, only the front end portion of the bottom substrate 211 is dipped into the chemical solution while, in another embodiment, the whole bottom substrate 211 is dipped into the chemical solution.

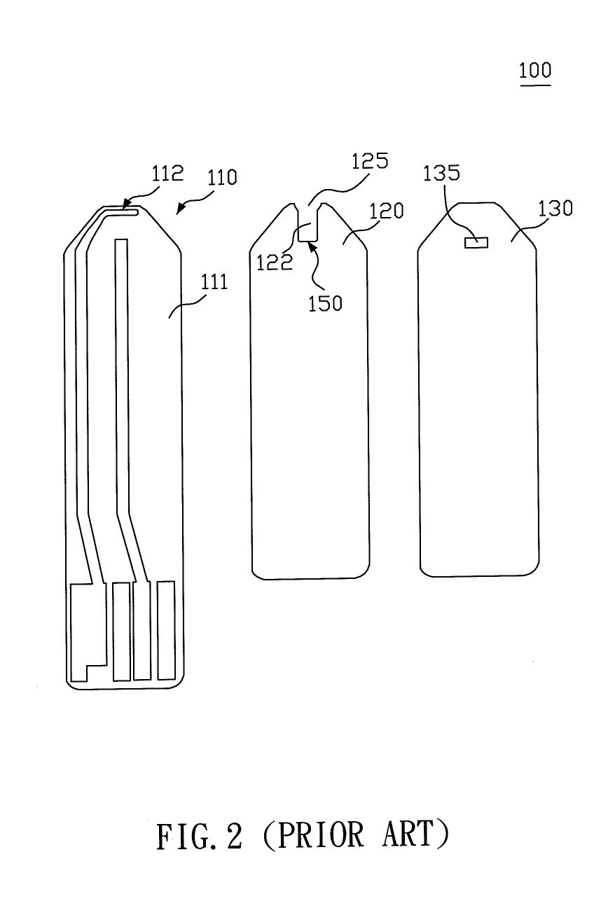

As shown in FIG. 4E, step S10: coating a reagent on at least a portion of the first reaction electrode 31a, the second reaction electrode 32a, or at least a portion of the bottom substrate 211 and covering with a top substrate 240. The top substrate 240 and the bottom substrate 211 define a flow channel and the position of the flow channel corresponds to that of the at least a portion of the bottom substrate 211, the first reaction electrode 31a or the second reaction electrode 32a. In one embodiment, the top substrate 240 can be formed into one piece and formed by mold injection. A groove is formed on the top substrate 240 and the position of the groove corresponds to that of the flow channel. In one embodiment, the top substrate 240 comprises a flow channel plate 120 and a top plate 130. The structures of the flow channel plate 120 and the top plate 130 can be implemented by the example shown in FIG. 2. Such a process known or developed in the future can be implemented by one of ordinary skill in the art and thus its details are not given. By the above steps, the electrochemical sensor strip 200 can be formed, as shown in FIG. 4F.

In addition, in one embodiment, the protective film 230 has a preset thickness enough to define a notch and the top substrate 240 comprises a plate. Preferably, step S06 comprises using a screen printing or inkjet printing technique to print the protective film 230 on the bottom substrate 211 where the protective film 230 has a thickness enough to form the flow channel 150 and to define a notch. Step S10 further comprises disposing the plate on the bottom substrate 211 such that the top substrate 240, the protective film 230 and the bottom substrate 211 define the flow channel corresponding to the notch.

If the reaction electrode of the electrochemical sensor strip 200 is coated with a different reagent, a different measurement item can be carried out, for example, blood lipid level test for cardiovascular disease, T-Cholesterol test, high density lipoprotein cholesterol (HDL-C) test, low density lipoprotein cholesterol (LDL-C) test, triglyceride (TG) test, myocardial infarction related LDH, CK-MB, CPK, GOT test, or gout related uric acid test, liver function related GOT and GPT test, etc.

However, a different reagent requires a reaction electrode made of different material to achieve a better test result. According to one embodiment of the invention, since the material of the circuit layer 220 is different from that of the electrode layer 320, they can be formed by different steps to produce different types of electrochemical sensor strips. Specifically, the bottom substrate 211 formed with the circuit layer 220 and the protective film 230 (partly-finished product of the electrochemical sensor strip 200) can be prepared in advance and then the reagent, the first reaction electrode 31a, and the second reaction electrode 32a can be formed according to product requirements. By such design, the partly-finished products are applicable to various types of electrochemical sensor strips 200 for mass production. Thus, the production cost can be reduced.

The function of the first circuit 221 and the second circuit 222 of the circuit layer 220 can be simplified to transmit the electrical signal from the first reaction electrode 31a and the second reaction electrode 32a to an external electrochemical sensing device and thus the low-cost conductive material such as copper or graphite can be used. The first reaction electrode 31a and the second reaction electrode 32a can be made of conductive material, such as noble metal like gold or palladium, having a better test result. Therefore, partial electrodes can be formed to reduce the usage of the noble metal like gold or palladium so as to reduce the production cost. Besides, since the first measurement electrode 31b and the second measurement electrode 32b are used to contact with the electrochemical sensing device and can be formed by noble metal like gold or palladium to reduce the contact resistance between the electrochemical sensor strip 200 and the electrochemical sensing device. Besides, in one embodiment, a batch of electrochemical sensor strips 200 can be placed in the electroplating solution or chemical solution together to form the electrode layer 320. Thus, it can be massively produced and the production cost can be reduced.

Although the present invention has been fully described by the above embodiments, the embodiments should not constitute the limitation of the scope of the invention. Various modifications or changes can be made by those who are skilled in the art without deviating from the spirit of the invention. Any embodiment or claim of the present invention does not need to reach all the disclosed objects, advantages, and uniqueness of the invention. Besides, the abstract and the title are only used for assisting the search of the patent documentation and should not be construed as any limitation on the implementation range of the invention.

What is claimed is:

1. A method for making an electrochemical sensor strip, the method comprising the following steps:
forming a circuit layer on a first substrate;
forming a protective film on the first substrate to have the protective film cover a first portion of the circuit layer;
forming an electrode layer on a second portion of the circuit layer, wherein the material of the electrode layer is different from that of the circuit layer; and
coating a reagent on at least a portion of the electrode layer or the first substrate and disposing a second substrate on the first substrate, wherein the first substrate and the second substrate define a flow channel and the flow channel is at a position corresponding to the position of the at least a portion of the electrode layer or the first substrate coated with the reagent.

2. The method according to claim 1, wherein the step of forming a protective film on the first substrate comprises using a screen printing technique or an inkjet printing technique to form the protective film on the first substrate.

3. The method according to claim 1, wherein the step of forming an electrode layer on a second portion of the circuit layer comprises using a deposition technique to form the electrode layer on the second portion of the circuit layer.

4. The method according to claim 3, wherein the deposition technique is an electroplating technique and the step of using a deposition technique to form the electrode layer on the second portion of the circuit layer comprises the following steps:
using a metal clamping tool to clamp the first substrate and to have the metal clamping tool be in contact with a portion of the circuit layer which is not covered by the protective film;
placing the second portion of the first substrate formed with the circuit layer and the protective film in an electroplating solution; and
applying a power source to the circuit layer through the metal clamping tool.

5. The method according to claim 3, wherein the deposition technique is an electroless plating technique.

6. The method according to claim 1, wherein
the circuit layer comprises a first circuit and a second circuit and the circuit layer comprises a first reaction electrode and a second reaction electrode;
the step of forming a protective film on the first substrate comprises having the protective film cover a central portion of the first circuit and the second circuit but not cover a first reaction portion and a first measurement portion on two ends of the first circuit and not cover a second reaction portion and a second measurement portion on two ends of the second circuit; and
the step of forming an electrode layer on a second portion of the circuit layer comprises forming the first reaction electrode and the second reaction electrode at the first reaction portion and the second reaction portion, respectively.

7. The method according to claim 6, wherein
the electrode layer further comprises a first measurement electrode and a second measurement electrode; and
the step of forming an electrode layer on a second portion of the circuit layer further comprises forming the first measurement electrode and the second measurement electrode at the first measurement portion and the second measurement portion, respectively

8. The method according to claim 1, wherein
the protective film has a thickness enough to contain the flow channel and has a notch;
the second substrate is a plate; and
the step of disposing a second substrate on the first substrate comprises placing the plate on the first substrate such that the first substrate, the protective film and the second substrate define the flow channel corresponding to the notch.
